(19) United States
(12) Patent Application Publication
(10) Pub. No.: US 2026/0333971 A1
(43) Pub. Date: Oct. 22, 2026

(54) DISPLAY PANEL, PIXEL CIRCUIT AND DRIVING METHOD THEREFOR

(71) Applicants: CHENGDU BOE OPTOELECTRONICS TECHNOLOGY CO., LTD., Sichuan (CN); BOE TECHNOLOGY GROUP CO., LTD., Beijing (CN)

(72) Inventor: Tiaomei ZHANG, Beijing (CN)

(21) Appl. No.: 19/109,679

(22) PCT Filed: Jul. 27, 2023
(86) PCT No.: PCT/CN2023/109663

§ 371 Date: Mar. 7, 2025

(51) Int. Cl. H10H 29/39; G09G 3/32; G09G 3/3233; H10D 86/40; H10D 86/60; H10H 29/49; H10K 59/123; H10K 59/126; H10K 59/131

(52) U.S. Cl. CPC H10H 29/39; G09G 3/32; G09G 3/3233; H10D 86/441; H10D 86/60; H10H 29/49; H10K 59/123; H10K 59/126; H10K 59/131; G09G 2300/0426; G09G 2300/043; G09G 2300/0819; G09G 2300/0842; G09G 2310/08; G09G 2320/0209; G09G 2320/0233; G09G 2320/0247; G09G 2320/045

(57) ABSTRACT

A display panel, a pixel circuit and a driving method therefor is disclosed. The pixel circuit includes a driving transistor, a compensation circuit, a write circuit, a first reset circuit and a second reset circuit, a first electrode of the driving transistor is used for receiving a first power source signal, and a second electrode thereof is connected to a light-emitting device; one of the first electrode and the second electrode is connected to a gate electrode thereof through the compensation circuit, and the other one receives a data signal through the write circuit; the first reset circuit is connected to one of the first electrode and the second electrode for inputting a first reset signal; the second reset circuit is connected to one of the first electrode and the second electrode for inputting a second reset signal; the first reset signal and the second reset signal have opposite polarities.

### CROSS-REFERENCE TO RELATED APPLICATIONS

The present application is a U.S. National Stage of International Application No. PCT/CN2023/109663, filed on Jul. 27, 2023, the content of which is incorporated by reference herein in its entireties for all purposes.

### TECHNICAL FIELD

The present disclosure relates to the field of display technology, and in particular to a display panel, a pixel circuit, and a driving method of the pixel circuit.

### BACKGROUND

For display panels that use organic light-emitting diodes as light-emitting devices, the light-emitting brightness of the light-emitting devices is generally controlled by pixel circuits. However, it is difficult for existing display panels to stably maintain the brightness of the screen when switching between high and low frequencies, and the screen is delayed and has the risk of screen flickering.

It should be noted that the information disclosed in the above background technology section is only used to enhance the understanding of the background of the present disclosure, and therefore may include information that does not constitute prior art known to those skilled in the art.

### SUMMARY

The present disclosure provides a display panel, a pixel circuit and a driving method of the pixel circuit.

According to an aspect of the present disclosure, there is provided a pixel circuit, including a drive transistor, a compensation circuit, a write circuit, a first reset circuit and a second reset circuit;
a first electrode of the drive transistor is configured to receive a first power signal, and a second electrode of the drive transistor is connected to a light-emitting device through a first light-emitting control circuit;
one of the first electrode and the second electrode of the drive transistor is connected to a gate electrode of the drive transistor through the compensation circuit, and the other one of the first electrode and the second electrode of the drive transistor receives a data signal through the write circuit;
the first reset circuit is connected to one of the first electrode and the second electrode of the drive transistor for inputting a first reset signal; the second reset circuit is connected to one of the first electrode and the second electrode of the drive transistor for inputting a second reset signal; the first reset signal and the second reset signal have opposite polarities.

According an aspect of the present disclosure, there is provided a driving method for a pixel circuit, the pixel circuit including a drive transistor, a compensation circuit, a write circuit, a first reset circuit, a second reset circuit, a first light-emitting control circuit and a second light-emitting control circuit;
a first electrode of the drive transistor receives a first power signal through the first light-emitting control circuit, and a second electrode of the drive transistor is connected to a light-emitting device through the second light-emitting control circuit; one of the first electrode and the second electrode of the drive transistor is connected to a gate electrode of the drive transistor through the compensation circuit, and the other one of the first electrode and the second electrode of the drive transistor receives a data signal through the write circuit; the first reset circuit is connected to one of the first electrode and the second electrode of the drive transistor; the second reset circuit is connected to one of the first electrode and the second electrode of the drive transistor;
the driving method includes:
in a first reset stage of a write frame, turning off the write circuit, the first reset circuit, the first light-emitting control circuit and the second light-emitting control circuit; turning on the second reset circuit, and inputting a second reset signal through the second reset circuit;
in a second reset stage of the write frame, turning off the write circuit, the second reset circuit, the first light-emitting control circuit and the second light-emitting control circuit; turning on the compensation circuit and the first reset circuit, and inputting a first reset signal through the first reset circuit; the first reset signal and the second reset signal have opposite polarities;
in a write stage of the write frame, turning off the first reset circuit, the second reset circuit, the first light-emitting control circuit and the second light-emitting control circuit; turning on the write circuit and the compensation circuit, and inputting the data signal through the write circuit;
in a third reset stage of the write frame, turning off the compensation circuit, the write circuit, the second reset circuit and the first light-emitting control circuit; turning on the first reset circuit and the second light-emitting control circuit, and inputting the first reset signal through the first reset circuit; and
in a light-emitting stage of the write frame, turning off the compensation circuit, the write circuit, the first reset circuit and the second reset circuit; turning on the first light-emitting control circuit and the second light-emitting control circuit.

According to an aspect of the present disclosure, there is provided a display panel, including a plurality of pixel circuits arranged in an array along a row direction and a column direction, the pixel circuit including a plurality of transistors, a storage capacitor, a data line and a power line, the transistors including a drive transistor, a write transistor, a compensation transistor, a first light-emitting control transistor, a second light-emitting control transistor, a first reset transistor and a second reset transistor;
a first electrode of the drive transistor is connected to the power line through the first light-emitting control transistor, and a second electrode of the drive transistor is connected to a light-emitting device through the second light-emitting control transistor; one of the first electrode and the second electrode of the drive transistor is connected to a gate electrode of the drive transistor through the compensation transistor, and the other one of the first electrode and the second electrode of the drive transistor is connected to the data line through the write transistor; the first reset transistor is connected to one of the first electrode and the second electrode of the drive transistor; the second reset transistor is connected to one of the first electrode and the second electrode of the drive transistor; the storage capacitor connects the gate electrode of the drive transistor and the power line; the power line is configured to input a first power signal, and the data line is configured to transmit a data signal;
the display panel includes:
a substrate;
a circuit layer, arranged on a side of the substrate, and including the pixel circuits;
a plurality of light-emitting devices, arranged on a side of the circuit layer away from the substrate, and one of the light-emitting devices is connected to the second electrode of the second light-emitting control transistor of one of the pixel circuits.

It should be understood that the above general description and the detailed description that follows are exemplary and explanatory only and do not limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. Obviously, the drawings described below are only some embodiments of the present disclosure, and for those skilled in the art, other drawings can also be obtained based on these drawings without creative work.

FIG. 1 is a schematic diagram of a display area and a peripheral area of an embodiment of the display panel of the present disclosure.

FIG. 2 is a cross-sectional principle diagram of an embodiment of the display panel of the present disclosure.

FIG. 3 is a principle diagram of a first embodiment of a pixel circuit of the present disclosure.

FIG. 4 is a principle diagram of a second embodiment of a pixel circuit of the present disclosure.

FIG. 5 is a principle diagram of a third embodiment of a pixel circuit of the present disclosure.

FIG. 6 is a principle diagram of a fourth embodiment of a pixel circuit of the present disclosure.

FIG. 7 is a timing diagram of an embodiment of a driving method of a pixel circuit of the present disclosure.

FIG. 8 is a timing diagram of another embodiment of a driving method of a pixel circuit of the present disclosure.

FIG. 9 is a timing diagram of still another embodiment of a driving method of a pixel circuit of the present disclosure.

FIG. 10 is a partial top view of an embodiment of a display panel of the present disclosure.

FIG. 11 is a partial top view of a light shielding layer and a first semiconductor layer in an embodiment of a display panel of the present disclosure.

FIG. 12 is a partial top view of a first semiconductor layer and a first gate layer in an embodiment of a display panel of the present disclosure.

FIG. 13 is a partial top view of a first semiconductor layer to a second semiconductor layer in an embodiment of a display panel of the present disclosure.

FIG. 14 is a partial top view of a first semiconductor layer to a third gate layer in an embodiment of a display panel of the present disclosure.

FIG. 15 is a partial top view of a first semiconductor layer to a first source-drain layer in an embodiment of a display panel of the present disclosure.

FIG. 16 to FIG. 23 are partial top views of respective film layers in an embodiment of a display panel of the present disclosure.

FIG. 24 is a partial top view of a light shielding layer and a first source-drain layer in an embodiment of a display panel of the present disclosure.

FIG. 25 is a partial top view of a first semiconductor layer to a first source-drain layer in another embodiment of a display panel of the present disclosure.

FIG. 26 is a partial top view of a first semiconductor layer to a first source-drain layer in another embodiment of a display panel of the present disclosure.

FIG. 27 is a partial top view of a first semiconductor layer to a first source-drain layer in another embodiment of a display panel of the present disclosure.

FIG. 28 is a partial top view of a light shielding layer and a first source-drain layer in an embodiment of a display panel of the present disclosure.

FIG. 29 is a partial top view of another embodiment of a display panel of the present disclosure.

FIG. 30 is a partial top view of a first source-drain layer in FIG. 28.

FIG. 31 is a partial top view of a second source-drain layer in FIG. 29.

### DETAILED DESCRIPTION

The example embodiments will now be described more fully with reference to the accompanying drawings. However, the example embodiments can be implemented in a variety of forms and should not be construed as being limited to the embodiments set forth herein; rather, these embodiments are provided so that the present disclosure will be comprehensive and complete and the concept of the example embodiments will be fully conveyed to those skilled in the art. The same reference numerals in the figures represent the same or similar structures, and their detailed descriptions will be omitted. In addition, the drawings are only schematic illustrations of the present disclosure and are not necessarily drawn to scale.

The terms “a”, “an”, “the”, “said”, and “at least one” are used to indicate the presence of one or more elements/components/etc. ; the terms “including” and “having” are used to indicate an open-ended inclusion and mean that there may be additional elements/components/etc. in addition to the listed elements/components/etc. ; the terms “first”, “second”, and “third”, etc. are used only as markers and are not intended to limit the number of their objects.

The row direction X and the column direction Y herein are only two intersecting directions, which may be mutually perpendicular directions. In the drawings of the present disclosure, the row direction X is horizontal and the column direction Y is vertical, but this is not limited thereto. If the display panel is rotated, the actual orientation of the row direction X and the column direction Y may change.

The “overlap” of feature A and feature B herein means that the orthographic projection of feature A on the substrate and the orthographic projection of feature B on the substrate at least partially overlap. Of course, it is also possible that the orthographic projections of feature A and feature B on a plane parallel to the substrate at least partially overlap.

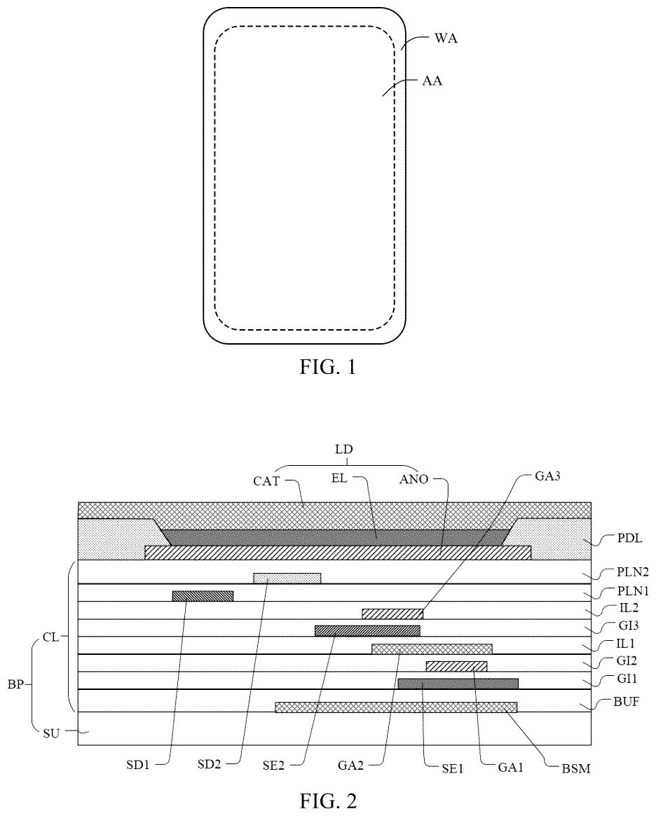

As shown in FIG. 1, the present disclosure also provides a display panel, which may include a display area AA and a peripheral area WA located outside the display area AA. The peripheral area WA may be a continuous annular area surrounding the display area AA, or a discontinuous area surrounding the display area AA.

As shown in FIG. 2, the display panel may include a driving backplane BP and a plurality of light-emitting devices LD disposed on one side of the driving backplane BP. Each light-emitting device LD is distributed along the row direction X and the column direction Y, and the light-emitting device LD may be driven to emit light by the driving circuit in the driving backplane BP to display an image.

As shown in FIG. 1 and FIG. 2, the light-emitting device LD may be located in the display area AA. The light-emitting device LD may be an OLED (organic light-emitting diode) using organic light-emitting materials; or an LED (light-emitting diode) using inorganic light-emitting materials, such as Micro LED (micrometer light-emitting diode) and Mini LED (sub-millimeter light-emitting diode); or a device such as QLED (quantum dot diode). The specific structure of the display panel is not specifically limited here, as long as it can display images.

As shown in FIG. 2, taking OLED as an example of the light-emitting device LD, the light-emitting device LD may include a first electrode ANO, a light-emitting layer EL, and a second electrode CAT stacked in sequence in a direction away from the driving backplane BP. By applying a first power signal VDD to the first electrode ANO and applying a second power signal VSS to the second electrode CAT, the light-emitting layer EL may be excited to emit light. The specific principle is not described in detail here. At the same time, in order to limit the range of the light-emitting device LD, a pixel definition layer PDL may be set on the driving backplane BP, which may have openings that expose each first electrode ANO, so that the range of the light-emitting device LD can be limited by each opening.

The driving circuit may include a pixel circuit in the display area AA and a peripheral circuit in the peripheral area WA. The pixel circuit may be distributed along the row direction X and the column direction Y. A pixel circuit may be connected to a first electrode of a light-emitting device LD, and a row of pixel circuits may be connected to a first electrode of each of the light-emitting devices in a row. Of course, the same pixel circuit may be connected to first electrodes of multiple light-emitting devices LD.

The peripheral circuit may be connected to the light-emitting device LD through the pixel circuit, and may apply a first power signal VDD to the first electrode ANO of the light-emitting device LD. The peripheral circuit may also include a light-emitting drive circuit and a gate drive circuit for scanning the pixel circuit. At the same time, the peripheral circuit may also be connected to the second electrode CAT of the light-emitting device LD, and may apply a second power signal VSS to the second electrode CAT. The current passing through the light-emitting device LD may be controlled through the pixel circuit, thereby controlling the brightness of the light-emitting device LD.

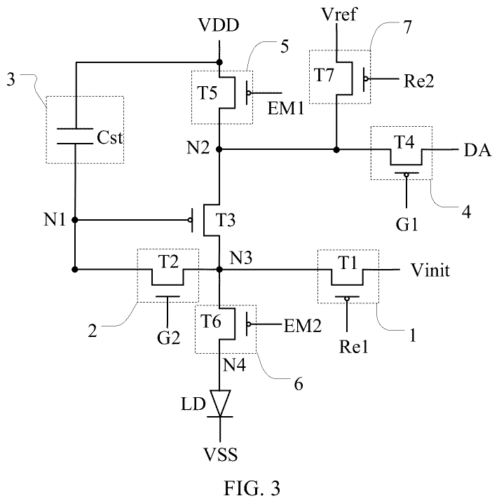

Taking a pixel circuit as an example, as shown in FIG. 3 to FIG. 6, as shown in FIG. 1, the pixel circuit may include a drive transistor T3, a compensation circuit 2, a write circuit 4, a first reset circuit 1 and a second reset circuit 7, where:

The first electrode of the drive transistor T3 can receive a first power signal VDD, and the second electrode is connected to the light-emitting device through the first light-emitting control circuit 5;

One of the first electrode and the second electrode of the drive transistor T3 is connected to its gate through the compensation circuit 2, and the other receives the data signal DA through the write circuit 4.

The first reset circuit 1 is connected to one of the first electrode and the second electrode of the drive transistor T3, and can input a first reset signal Vinit. The second reset circuit 7 is connected to one of the first electrode and the second electrode of the drive transistor T3, and can input a second reset signal Vref; the first reset signal Vinit and the second reset signal Vref have opposite polarities.

The pixel circuit of the embodiment of the present disclosure inputs a second reset signal Vref to at least one of the first electrode and the second electrode of the drive transistor T3 through the second reset circuit 7, and increases a large bias voltage to the drive transistor T3 to improve hysteresis, so that the brightness of the picture can be maintained when switching between high and low frequencies, reducing the risk of screen flickering, and improving the display effect of the display panel. At the same time, the first reset signal Vinit can be input to the gate of the drive transistor T3 through the first reset circuit 1 to eliminate the influence of the data of the previous frame image.

As shown in FIG. 3, in some embodiments of the present disclosure, the pixel circuit also includes an energy storage circuit 3, a first light-emitting control circuit 5 and a second light-emitting control circuit 6;

The first electrode of the drive transistor T3 can receive the first power signal VDD through the first light-emitting control circuit 5, and the second electrode is connected to the light-emitting device through the second light-emitting control circuit 6. The energy storage circuit 3 can be connected to the gate electrode of the drive transistor T3 and can receive the first power signal VDD for continuously controlling the voltage of the drive transistor T3.

The write circuit 4 can be turned on in response to the first scan signal G1, the compensation circuit 2 can be turned on in response to the second scan signal G2, the first reset circuit 1 can be turned on in response to the first reset control signal Re1, the second reset circuit 7 can be turned on in response to the second reset control signal Re2, the first light-emitting control circuit 5 can be turned on in response to the first light-emitting control signal EM1, and the second light-emitting control circuit 6 can be turned on in response to the second light-emitting control signal EM2.

Furthermore, each pixel circuit may include multiple transistors and capacitors, and the active parts of respective transistors may be arranged in the same layer, and may be made of semiconductor materials such as polysilicon; or, the active parts of some transistors may be in different layers from the active parts of other transistors, for example, the active parts of some transistors may be polysilicon, and the active parts of some transistors may be metal oxides such as IGZO.

Each transistor may include a gate electrode, a first electrode, and a second electrode, and the turn-on and turn-off between the first electrode and the second electrode may be achieved by controlling the voltage of the gate; the first electrode may be a source electrode, and the second electrode may be a drain electrode. Of course, the first electrode may also be a drain electrode, and the second electrode may also be a source electrode. Specifically, if a signal is input from the first electrode, then the first electrode is a source electrode, and the second electrode is a drain electrode; if a signal is input from the second electrode, then the second electrode is a source electrode, and the first electrode is a drain electrode. That is, if the first electrode and the second electrode of the same transistor both need to input a signal, the source electrode and the drain electrode will be converted depending on the input signal.

The transistor may be a P-type transistor or an N-type transistor. For example, for a P-type transistor, when the gate receives a high level, the first and second electrodes are turned off; when the gate receives a low level, the first and second electrodes are turned on. For an N-type transistor, when its gate receives a high level, the first and second electrodes are turned on; when it receives a low level, the first and second electrodes are turned off.

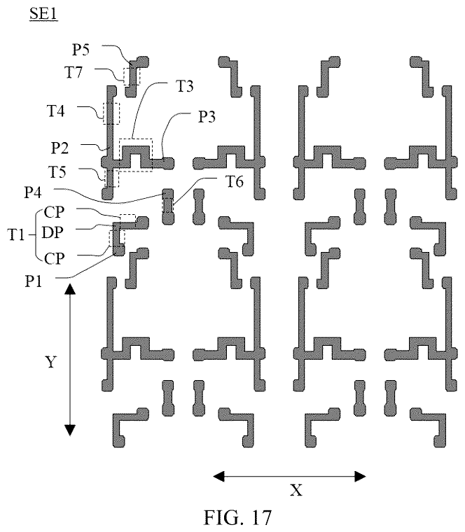

As shown in FIG. 3 to FIG. 6 and FIG. 10 to FIG. 23, the write circuit 4 includes a write transistor T4. The on and off of the write transistor T4 can be controlled by a first scan signal G1 transmitted to the gate of the write transistor T4. The compensation circuit 2 includes a compensation transistor T2. The on and off of the compensation transistor T2 can be controlled by a second scan signal G2 transmitted to the gate of the compensation transistor T2.

The first reset circuit 1 includes a first reset transistor T1. The on and off of the first reset transistor T1 can be controlled by a first reset control signal Re1 transmitted to the gate of the first reset transistor T1. The second reset circuit 7 includes a second reset transistor T7. The on and off of the second reset transistor T7 can be controlled by a second reset control signal Re2 transmitted to the gate of the second reset transistor T7.

The first light-emitting control circuit 5 includes a first light-emitting control transistor T5. The on and off of the first light-emitting control transistor T5 can be controlled by a first light-emitting control signal EM1 transmitted to the gate of the first light-emitting control transistor T5. The second light-emitting control circuit 6 includes a second light-emitting control transistor T6. The on and off of the second light-emitting control transistor T6 can be controlled by a second light-emitting control signal EM2 transmitted to the gate of the second light-emitting control transistor T6.

The energy storage circuit 3 includes a storage capacitor Cst. A first plate Cst1 of the storage capacitor Cst can be connected to the gate of the drive transistor T3, and a second plate Cst2 of the storage capacitor Cst can be configured to receive the first power signal VDD.

The gate electrode of the first light-emitting control transistor T5 is connected to the first light-emitting control line EML1 that transmits the first light-emitting control signal EM1, the first electrode can be connected to a power line VDL for receiving the first power signal VDD, and the second electrode is connected to the first electrode of the drive transistor T3 at the N2 node.

The second electrode of the drive transistor T3 is connected to the first electrode of the second light-emitting control transistor T6 at the N3 node. The second electrode of the second light-emitting control transistor T6 is connected to the first electrode of the light-emitting device, and the gate electrode of the second light-emitting control transistor T6 can be connected to the second light-emitting control line EML2 that transmits the second light-emitting control signal EM2. The first plate Cst1 of the storage capacitor Cst is connected to the gate electrode of the drive transistor T3 at the N1 node, and the second plate Cst2 is connected to the power line VDL that transmits the first power signal VDD. The first electrode of the write transistor T4 can be connected to the data line DAL for transmitting the data signal DA, and the second electrode can be connected to the first electrode or the second electrode of the drive transistor T3. The gate electrode of the compensation transistor T2 can be connected to the second scan line GL2 for transmitting the second scan signal G2, the first electrode can be connected to the N2 node or the N3 node, and the second electrode is connected to the N1 node.

The gate electrode of the first reset transistor T1 is connected to the first reset control line REL1 for transmitting the first reset control signal Re1, the first electrode of the first reset transistor T1 is connected to the first reset signal line for transmitting the first reset signal Vinit, and the second electrode of the first reset transistor T1 is connected to the N2 node or the N3 node. The gate electrode of the second reset transistor T7 is connected to the second reset control line REL2 for transmitting the second reset control signal Re2, the first electrode of the second reset transistor T7 is connected to the second reset signal line for transmitting the second reset signal Vref, and the second electrode of the second reset transistor T7 is connected to the N2 node or the N3 node.

The following is an exemplary description of different schemes of the pixel circuit according to the different positions where the write transistor T4, the compensation transistor T2, the first reset transistor T1 and the second reset transistor T7 are connected:

### First Embodiment

As shown in FIG. 3, the first reset circuit 1 and the compensation circuit 2 are both connected to the second electrode of the drive transistor T3, and the second reset circuit 7 and the write circuit 4 are both connected to the first electrode of the drive transistor T3. For example, the second electrode of the first reset transistor T1, the first electrode of the compensation transistor T2, the second electrode of the drive transistor T3 and the first electrode of the second light-emitting control transistor T6 are connected to the N3 node; the second electrode of the compensation transistor T2, the first plate Cst1 of the storage capacitor Cst and the gate electrode of the drive transistor T3 are connected to the N1 node; the second electrode of the second reset transistor T7, the second electrode of the write transistor T4, the second electrode of the first light-emitting control transistor T5 and the first electrode of the drive transistor T3 are connected to the N2 node.

### Second Embodiment

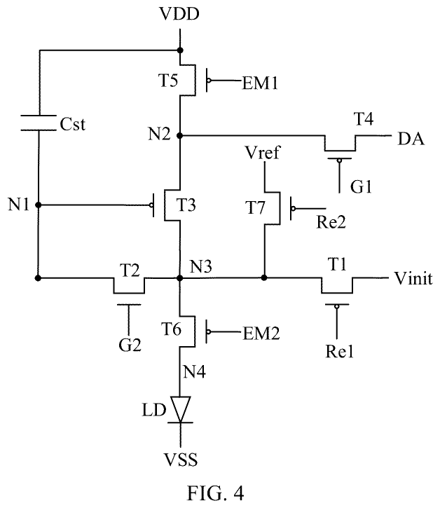

As shown in FIG. 4, the first reset circuit 1, the second reset circuit 7 and the compensation circuit 2 are connected to the second electrode of the drive transistor T3, and the write circuit 4 is connected to the first electrode of the drive transistor T3. For example, the second electrode of the first reset transistor T1, the second electrode of the second reset transistor T7, the first electrode of the compensation transistor T2, the first electrode of the second light-emitting control transistor T6 and the second electrode of the drive transistor T3 are connected to the N3 node; the second electrode of the write transistor T4, the first electrode of the drive transistor T3 and the first electrode of the first light-emitting control transistor T5 are connected to the N2 node; the second electrode of the compensation transistor T2, the first plate Cst1 of the storage capacitor Cst and the gate electrode of the drive transistor T3 are connected to the N1 node.

### Third Embodiment

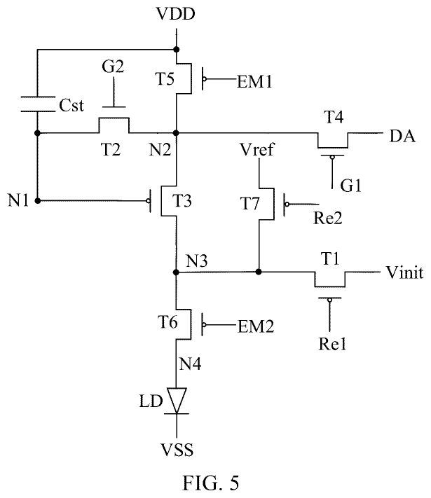

As shown in FIG. 5, the compensation circuit 2 and the first reset circuit 1 are connected to the first electrode of the drive transistor T3, and the second reset circuit 7 and the write circuit 4 are connected to the second electrode of the drive transistor T3. For example, the second electrode of the first reset circuit 1, the first electrode of the compensation circuit 2, the second electrode of the first light-emitting control transistor T5 and the first electrode of the drive transistor T3 are connected to the N2 node; the second electrode of the compensation circuit 2, the gate electrode of the drive transistor T3 and the first plate Cst1 of the storage capacitor Cst are connected to the N1 node; the second electrode of the second reset circuit 7, the second electrode of the write transistor T4, the second electrode of the drive transistor T3 and the first electrode of the second light-emitting control transistor T6 are connected to the N3 node.

### Fourth Embodiment

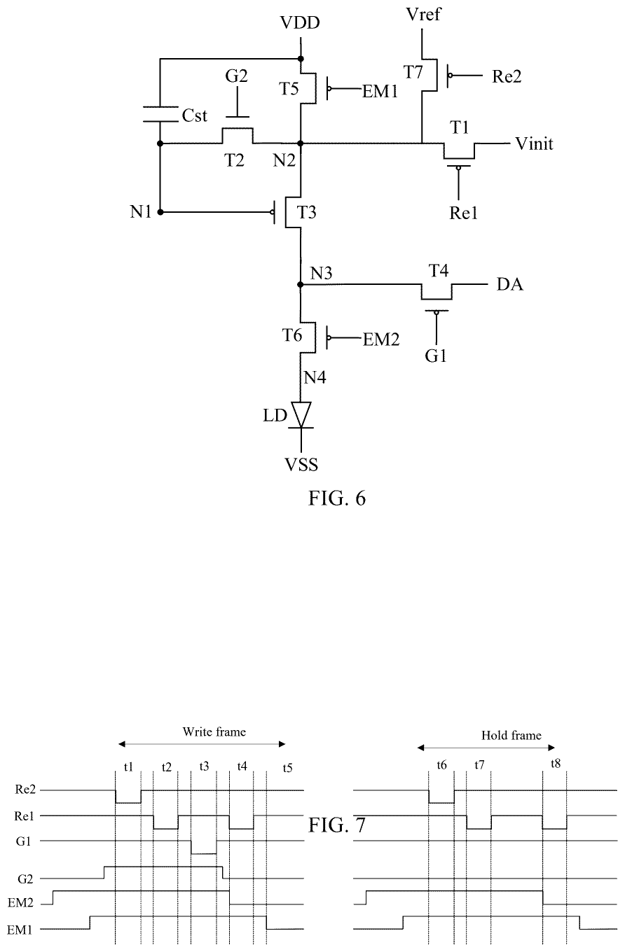

As shown in FIG. 6, the first reset circuit 1, the second reset circuit 7 and the compensation circuit 2 are connected to the first electrode of the drive transistor T3, and the write circuit 4 is connected to the second electrode of the drive transistor T3. For example, the second electrode of the first reset transistor T1, the second electrode of the second reset transistor T7, the first electrode of the compensation transistor T2, the second electrode of the first light-emitting control transistor T5 and the first electrode of the drive transistor T3 are connected to the N2 node; the second electrode of the write transistor T4, the second electrode of the drive transistor T3 and the first electrode of the second light-emitting control transistor T6 are connected to the N3 node; the second electrode of the compensation transistor T2, the gate of the drive transistor T3 and the first plate Cst1 of the storage capacitor Cst are connected to the N1 node.

The principle of the above pixel circuit is explained below in combination with the driving method of the pixel circuit of the present disclosure:

When displaying an image, the display panel can divide a display frame into a write frame and at least one hold frame after the write frame. The duration of the write frame under different refresh rates can be the same. By adjusting the duration of the hold frame, the actual display effect can meet the corresponding refresh rate, which is particularly suitable for the case where low frequency display is required. In the write frame, reset, writing of data signal DA and light emission can be realized, while in the hold frame, no data signal DA is written, light emission is not performed, and only the reset process is performed, that is, low frequency display is realized by inserting frames through hold frames.

The driving method of the pixel circuit of the above embodiment is described with an example where a display frame includes a write frame and a hold frame, and the compensation transistor T2 is an N-type transistor, and the other transistors are P-type transistors:

As shown in FIG. 7 to FIG. 9, the write frame may include a first to third reset stages (t1, t2, t4), the write stage t3 and the light-emitting stage t5, and the hold frame may include a first to third reset stages (t6-t8), but not include the light-emitting stage, so the light emission may not be performed in the hold frame, specifically:

In the first reset stage t1 of the write frame, the write circuit 4, the first reset circuit 1, the first light-emitting control circuit 5 and the second light-emitting control circuit 6 can be turned off; the second reset circuit 7 is turned on, and the second reset signal Vref is input through the second reset circuit 7.

For example: the first scan signal G1, the first reset control signal Re1, the first light-emitting control signal EM1 and the second light-emitting control signal EM2 are all at high level, so that the write transistor T4, the first reset control transistor, the first light-emitting control transistor T5 and the second light-emitting control transistor T6 are turned off; the second reset control signal Re2 is at low level, so that the second reset control transistor is turned on; the second reset signal Vref is input through the second reset transistor T7 to refresh the N2 node. The second reset signal Vref can be a high level signal, thereby adding a large bias voltage to the drive transistor T3 to improve the hysteresis, so that the brightness of the picture can be maintained when switching between high and low frequencies, reducing the risk of screen flickering and improving the display effect of the display panel. At the same time, when the second reset signal Vref is at high level, the gate-source (gate electrode and first electrode) voltage difference of the drive transistor T3 can turn on the drive transistor T3, and the N3 node is refreshed while refreshing the N2 node.

In the second reset stage t2 of the write frame, the write circuit 4, the second reset circuit 7, the first light-emitting control circuit 5 and the second light-emitting control circuit 6 can be turned off; the compensation circuit 2 and the first reset circuit 1 are turned on, and the first reset signal Vinit is input through the first reset circuit 1; the first reset signal Vinit and the second reset signal Vref have opposite polarities.

For example, the first scan signal G1, the second reset control signal Re2, the first light control signal EM1 and the second light control signal EM2 are at high level, the write transistor T4, the second reset transistor T7, the first light-emitting control transistor T5 and the second light-emitting control transistor T6 are all turned off; the second scan signal G2 and the first reset control signal Re1 are both at low level, the compensation transistor T2 and the first reset transistor T1 are turned on; the first reset signal Vinit is input through the first reset transistor T1, the N1 and N3 nodes are reset, the residual voltage is eliminated, and the influence of the previous frame image is avoided. The first reset signal Vinit and the second reset signal Vref have opposite polarities. For example, the first reset signal Vinit is a low level signal, and the second reset signal Vref is a high level signal.

In the write stage t3 of the write frame, the first reset circuit 1, the second reset circuit 7, the first light-emitting control circuit 5 and the second light-emitting control circuit 6 are turned off; the write circuit 4 and the compensation circuit 2 are turned on, and the data signal DA is input through the write circuit 4.

For example: the first reset control signal Re1, the second reset control signal Re2, the first light-emitting control signal EM1 and the second light-emitting control signal EM2 are at high level, the first reset transistor T1, the second reset transistor T7, the first light-emitting control transistor T5 and the second light-emitting control transistor T6 are turned off; the first scan signal G1 and the second scan signal G2 are at low level, the write transistor T4 and the compensation transistor T2 are turned on. At this time, the data signal DA can be written to the N1 node through the write transistor T4 and the compensation transistor T2 until the voltage at the N1 node reaches Vdata+Vth, so that the gate-source voltage difference Vgs of the drive transistor T3 is Vth. At this time, the drive transistor T3 is turned off. Vth is the threshold voltage of the drive transistor T3, and Vdata is the voltage of the data signal. Thus, the threshold voltage is written to the N1 node and stored in the storage capacitor Cst.

In the third reset stage t4 of the write frame, the compensation circuit 2, the write circuit 4, the second reset circuit 7 and the first light-emitting control circuit 5 are turned off; the first reset circuit 1 and the second light-emitting control circuit 6 are turned on, and the first reset signal Vinit is input through the first reset circuit 1.

For example, the first scan signal G1, the second scan signal G2, the second reset control signal Re2 and the first light-emitting control signal EM1 are at high level, the compensation transistor T2, the write transistor T4, the second reset transistor T7 and the first light-emitting control transistor T5 are turned off; the first reset control signal Re1 and the second light-emitting control signal EM2 are at low level, the first reset transistor T1 and the second light-emitting control transistor T6 are turned on; the first reset signal Vinit is input to the N4 node through the first reset transistor T1 and the second light-emitting control transistor T6 to reset the first electrode of the light-emitting device and eliminate the influence of the previous frame image.

In the light-emitting phase t5 of the write frame, the compensation circuit 2, the write circuit 4, the first reset circuit 1 and the second reset circuit 7 are turned off; the first light-emitting control circuit 5 and the second light-emitting control circuit 6 are turned on.

For example, the first scan signal G1, the second scan signal G2, the first reset control signal Re1 and the second reset control signal Re2 are at high level, the compensation transistor T2, the write transistor T4, the first reset transistor T1 and the second reset transistor T7 are turned off; the first light-emitting control signal EM1 and the second light-emitting control signal EM2 are at low level, so that the first light-emitting control transistor T5 and the second light-emitting control transistor T6 are turned on.

Under the action of the storage capacitor Cst, the drive transistor T3 outputs a current, and the output current satisfies the following formula:

I=(μ WCox/2L)(Vgs−Vth)²;

I is the output current of the drive transistor T3; μ is the carrier mobility; Cox is the gate capacitance per unit area, W is the channel width of the drive transistor T3, and L is the channel length of the drive transistor T3.

According to the above formula for the output current of the drive transistor T3, the gate voltage Vdata+Vth and the source voltage VDD of the drive transistor T3 in the pixel circuit of the present disclosure are substituted into the above formula to obtain: the output current I of the drive transistor T3=(μ WCox/2L)(Vdata+Vth−VDD−Vth)². It can be seen that the output current of the pixel circuit has nothing to do with the threshold voltage Vth of the drive transistor T3, but only with Vdata, thereby eliminating the influence of the threshold voltage of the drive transistor T3 on its output current, and the output current can be controlled only by the voltage of the data signal DA, so as to control the brightness of the light-emitting device.

As shown in FIG. 7 to FIG. 9, in the first reset stage t6 of the hold frame, the write circuit 4, the first reset circuit 1, the first light-emitting control circuit 5 and the second light-emitting control circuit 6 are turned off; the second reset circuit 7 is turned on, and the second reset signal Vref is input through the second reset circuit 7.

The actions performed in the first reset stage of the hold frame can be the same as the actions performed in the first reset stage of the write frame, which will not be described in detail here. In the first reset stage, the N2 node can be refreshed, and the second reset signal Vref can be a high-level signal, thereby adding a large bias voltage to the drive transistor T3 to improve hysteresis, so that the brightness of the picture can be maintained when switching between high and low frequencies. At the same time, when the second reset signal Vref is at high level, the gate-source (gate electrode and the first electrode) voltage difference of the drive transistor T3 can turn on the drive transistor T3, and the N3 node is refreshed while refreshing the N2 node.

In the second reset stage t7 of the hold frame, the write circuit 4, the second reset circuit 7, the first light-emitting control circuit 5 and the second light-emitting control circuit 6 are turned off; the compensation circuit 2 and the first reset circuit 1 are turned on, and the first reset signal Vinit is input through the first reset circuit 1.

The actions performed in the second reset stage of the hold frame can be the same as those performed in the second reset stage of the write frame, which will not be described in detail here. The first reset signal Vinit is input through the first reset transistor T1 to reset the N1 and N3 nodes, eliminate the residual voltage, and avoid the influence of the previous frame image.

In the third reset stage t8 of the hold frame, the compensation circuit 2, the write circuit 4, the second reset circuit 7 and the first light-emitting control circuit 5 are turned off; the first reset circuit 1 and the second light-emitting control circuit 6 are turned on, and the first reset signal Vinit is input through the first reset circuit 1.

The action performed in the third reset stage of the hold frame can be the same as the action performed in the third reset stage of the write frame, which will not be described in detail here. The first reset signal Vinit is input to the N4 node through the first reset transistor T1 and the second light-emitting control transistor T6 to reset the first electrode of the light-emitting device and eliminate the influence of the previous frame image.

Further, as shown in FIG. 7 to FIG. 9, in some embodiments of the present disclosure, in the first reset stage t1 of the write frame and the hold frame, the compensation circuit 2 can also be turned on. For example, the second scan signal G2 is at low level, the compensation transistor T2 is turned on, and the N1 node is refreshed by the second reset signal Vref. Since the second reset signal Vref is at high level, leakage can be prevented and the internal defects of the drive transistor T3 can be improved. Of course, in the first reset stage, the compensation circuit 2 can also be turned off.

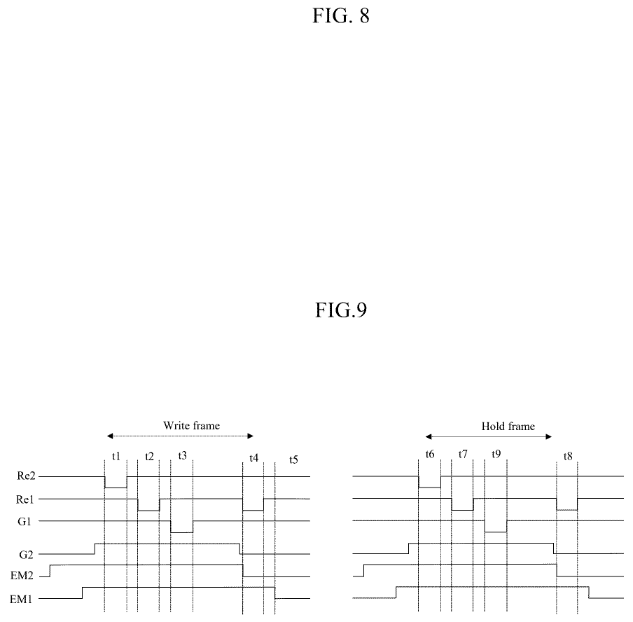

Further, as shown in FIG. 8, in some embodiments of the present disclosure, in the hold frame, the drive transistor T3 can be refreshed by using the data signal DA, and the driving method further includes:

In the fourth reset stage t9 of the hold frame, the first reset circuit 1, the second reset circuit 7, the first light-emitting control circuit 5 and the second light-emitting control circuit 6 are turned off; the write circuit 4 and the compensation circuit 2 are turned on, and the data signal DA is input through the write circuit 4.

For example, the first reset control signal Re1, the second reset control signal Re2, the first light-emitting control signal EM1 and the second light-emitting control signal EM2 are all at high level, the first reset transistor T1, the second reset transistor T7, the first light-emitting control transistor T5 and the second light-emitting control transistor T6 are turned off; the first scan signal G1 and the second scan signal G2 are at low level, the write transistor T4 and the compensation transistor T2 are turned on, the data signal DA is input through the write circuit 4, and the drive transistor T3 is refreshed by the data signal DA, that is, the N2, N3 and N1 nodes are refreshed to improve the hysteresis.

The fourth reset stage mentioned above may be located before the third reset stage and after the second reset stage, and the action in the fourth reset stage may be the same as that of the write stage, but since the compensation frame does not have a light-emitting stage, light is not emitted in the hold frame.

In addition, as shown in FIG. 9, in some embodiments, in the write frame, the third reset stage may be located after the write stage, and between the light-emitting stages. The duration between the write stage and the third reset stage may be greater than the duration of the write stage, thereby extending the write time of the threshold voltage. Correspondingly, in the hold frame, the duration between the fourth reset stage and the third reset stage may be the same as the duration between the write stage and the third reset stage, and less than the fourth reset stage. Of course, in some embodiments, the duration between the write stage and the third reset stage may also be less than the duration of the write stage.

It can be concluded from the above driving method that, for the same row of pixel circuits, the first light-emitting control signal EM1 and the second light-emitting signal received by the pixel circuits have a timing difference, and are not synchronous signals. Therefore, the difference between the first light-emitting control signal EM1 and the second light-emitting signal of the pixel circuits in different rows can be used to multiplex the first light-emitting control signal EM1 and the second light-emitting signal, without independently providing the first light-emitting control signal EM1 and the second light-emitting signal for each row of pixel circuits.

In some embodiments of the present disclosure, the first light-emitting control signal EM1 input to the n-th row of pixel circuits can be multiplexed into the second light-emitting control signal EM2 input to the (n+i)-th row of pixel circuits. That is, the first light-emitting control signal EM1 of the n-th row of pixel circuits is also used as the second light-emitting control signal EM2 input to the (n+i)-th row of pixel circuits, n and i are positive integers, i can be 1, 2, etc. In this way, the structure of the light-emitting drive circuit can be simplified, the occupied space can be reduced, the operating efficiency can be improved, and the difference in brightness between rows (the brightness of the light-emitting devices corresponding to different rows of pixel circuits) can also be reduced.

In some embodiments of the present disclosure, the first scan signal G1 input to the n-th row pixel circuit can be multiplexed as the second reset control signal Re2 input to the (n+j)-th row pixel circuit. That is, the first scan signal G1 of the n-th row pixel circuit is also used as the second reset control signal Re2 input to the (n+i)-th row pixel circuit, n and j are positive integers, j can be 1, 2, etc., and j can be equal to i. In this way, the structure of the gate drive circuit can be simplified, the occupied space can be reduced, the operating efficiency can be improved, and the brightness difference between rows can be reduced.

It should be noted that although the respective steps of the driving method in the present disclosure are described in a specific order in the accompanying drawings, this does not require or imply that these steps must be performed in this specific order, or that all the steps shown must be performed to achieve the desired result. Additionally, or alternatively, some steps can be omitted, multiple steps can be combined into one step, and/or one step can be decomposed into multiple steps, etc.

The embodiment of the present disclosure also provides a display panel, which may include a pixel circuit of any of the above embodiments. The specific structure and beneficial effects of the pixel circuit can refer to the above embodiments, which will not be described in detail here. The display panel is described in detail in combination with the pixel circuit:

As shown in FIG. 2, the driving backplane BP may include a substrate SU and a circuit layer CL. The substrate SU may be a flexible transparent material such as polyimide, or a hard transparent material such as glass. The circuit layer CL is arranged on a side of the substrate SU and includes a pixel circuit. The light-emitting device may be arranged on a side of the circuit layer CL away from the substrate SU, and a light-emitting device is connected to a second electrode of a second light-emitting control transistor T6 of a pixel circuit.

The circuit layer CL is described in detail below:

As shown in FIG. 2, the compensation transistor T2 of the pixel circuit is an N-type transistor, and other transistors are P-type transistors. The circuit layer CL includes a light shielding layer BSM, a first semiconductor layer SE1, a first gate layer GA1, a second gate layer GA2, a second semiconductor layer IG, a third gate layer GA3, a first source-drain layer SD1, and a second source-drain layer SD2, which are sequentially distributed in a direction away from the substrate SU, where:

The light shielding layer BSM is arranged on one side of the substrate SU, and its material can be metal or other conductive and light-shielding materials. The light shielding layer BSM can at least overlap with the drive transistor T3 to avoid the influence of the bottom signal and light on the drive transistor T3.

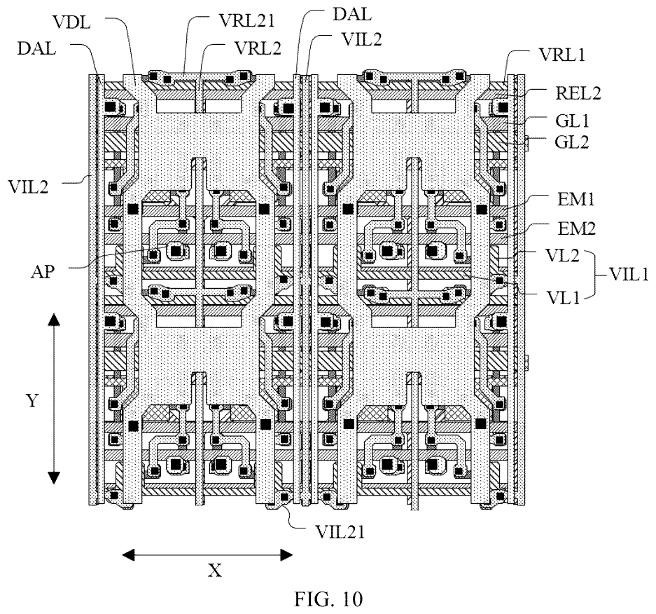

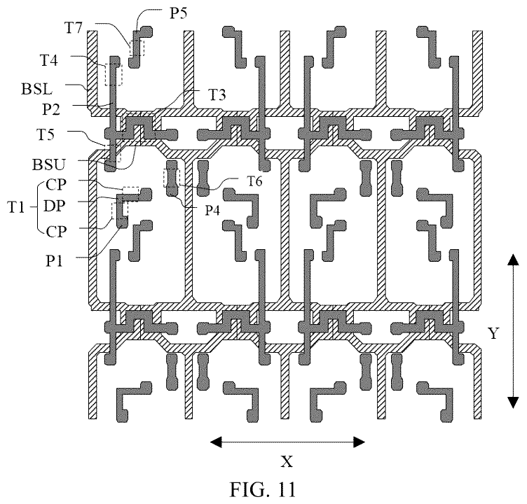

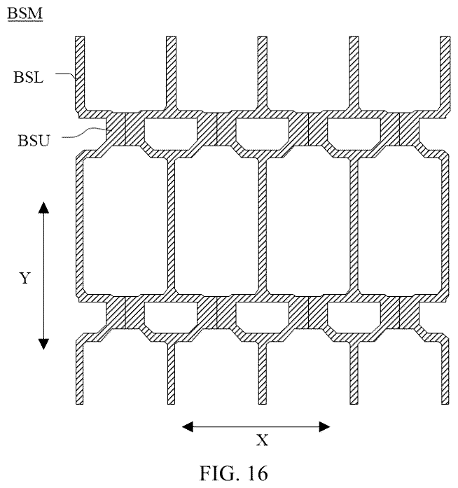

As shown in FIG. 10, FIG. 11 and FIG. 16, in some embodiments of the present disclosure, the light shielding layer BSM includes a plurality of light shielding units BSU distributed in an array, and each light shielding unit BSU overlaps with the active part of each drive transistor T3. The light shielding units BSUs in the same row are connected, and the light shielding units BSUs in the same column can be connected through a connecting line BSL, so that the light shielding layer BSM is connected as a whole. At the same time, the light shielding layer BSM can be connected to the power line VDL, or it can also be connected to other constant DC signals, which can reduce the impedance of signal transmission on the one hand, and can shield the signal through the DC signal on the other hand. Taking the connection of the light shielding layer BSM to the power line VDL as an example, a first power bus and a second power bus can be set in the peripheral area WA, each power line VDL can be connected to the first power bus, and the first power signal VDD is transmitted through the first power bus. The second power bus can be connected to the second electrode of the light-emitting device, and the second power signal VSS is transmitted through the second power bus. At the same time, the connecting line BSL of the light shielding layer BSM can be connected to the first power bus in the peripheral area WA. Of course, the light shielding unit BSU or the connecting line BSL can also be connected to the power line VDL in the display area AA.

As shown in FIG. 10 to FIG. 12 and FIG. 17, the first semiconductor layer SE1 is disposed on a side of the light shielding layer BSM away from the light shielding layer BSM, and the material of the first semiconductor layer SE1 may be polysilicon. The first semiconductor layer SE1 may include active parts of a drive transistor T3, a write transistor T4, a first light-emitting control transistor T5, a second light-emitting control transistor T6, a first reset transistor T1, and a second reset transistor T7.

In some embodiments of the present disclosure, the first semiconductor layer SE1 may include first to fifth semiconductor parts (P1-P5), the active part of the first reset transistor T1 is located in the first semiconductor part P1; the active parts of the write transistor T4 and the first light-emitting control transistor T5 are located in the second semiconductor part P2; the active part of the drive transistor T3 is located in the third semiconductor part P3, and the third semiconductor part P3 may be connected to the second semiconductor part P2; the active part of the second light-emitting control transistor T6 is located in the fourth semiconductor part P4; the active part of the second reset transistor T7 is located in the fifth semiconductor part P5.

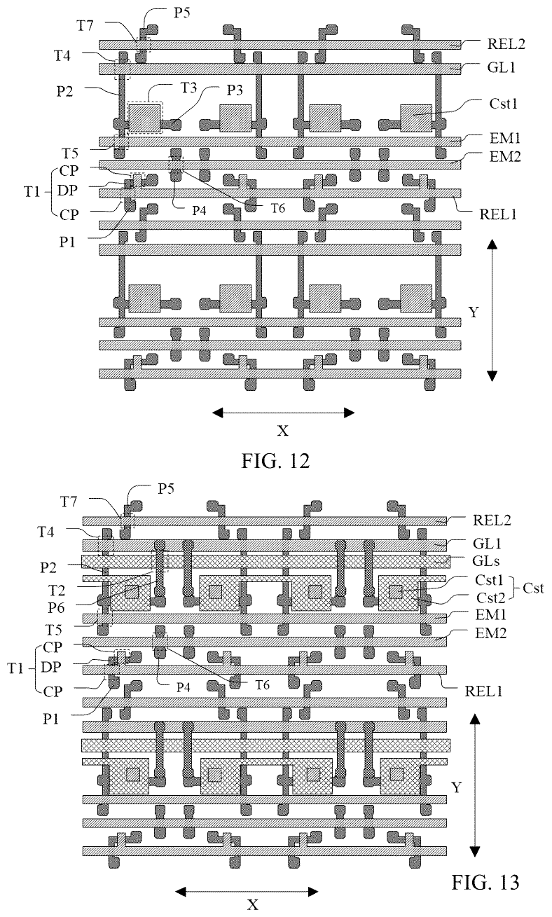

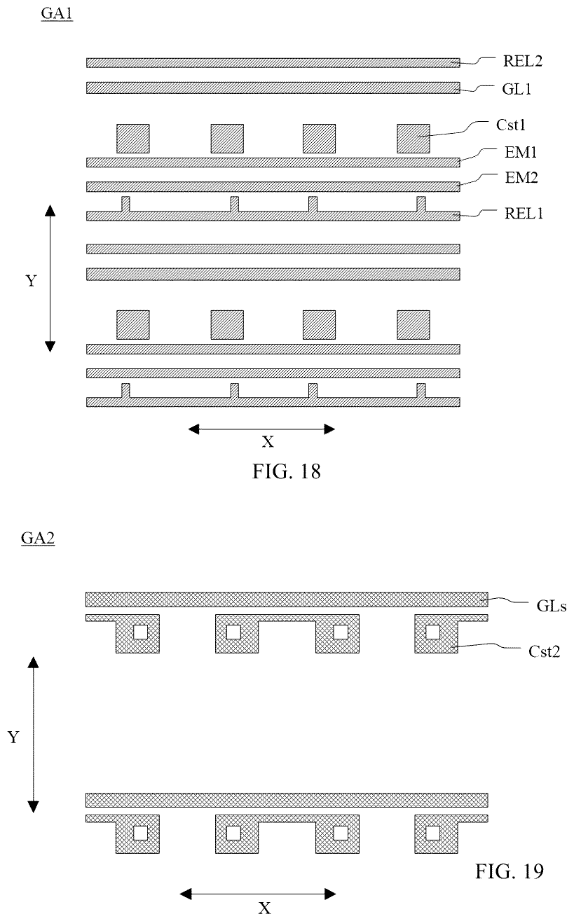

As shown in FIG. 10, FIG. 12 and FIG. 18, the first gate layer GA1 is arranged on a side of the first semiconductor layer SE1 away from the substrate SU, and overlaps with the first semiconductor layer SE1; the first gate layer GA1 may include a first plate Cst1 of the storage capacitor Cst, and gate electrodes of a drive transistor T3, a write transistor T4, a first light-emitting control transistor T5, a second light-emitting control transistor T6, a first reset transistor T1 and a second reset transistor T7.

In some embodiments of the present disclosure, the first gate layer GA1 may include a first plate Cst1 of a storage capacitor Cst and a first scan line GL1, a first light-emitting control line EML 1, a second light-emitting control line EML2, a first reset control line REL1, and a second reset control line REL2 extending along a row direction X, where:

The first plate Cst1 overlaps with the third semiconductor part, and the overlapping area is the gate electrode of the drive transistor T3; the first scan line GL1 overlaps with the second semiconductor part, and the overlapping area is the gate electrode of the write transistor T4; the first light-emitting control line EML1 overlaps with the second semiconductor part, and the overlapping area is the gate electrode of the first light-emitting control transistor T5; the second light-emitting control line EML2 overlaps with the fourth semiconductor layer, and the overlapping area is the gate electrode of the second light-emitting control transistor T6; the first reset control line REL1 overlaps with the first semiconductor part, and the overlapping area is the gate electrode of the first reset transistor T1; the second reset control line REL2 overlaps with the fifth semiconductor part P5, and the overlapping area is the gate electrode of the second reset transistor T7.

As shown in FIG. 10, FIG. 13 and FIG. 19, the second gate layer GA2 is arranged on a side of the first gate layer GA1 away from the substrate SU, and includes the second plate Cst2 of the storage capacitor Cst, and the second plate Cst2 overlaps with the first plate Cst1.

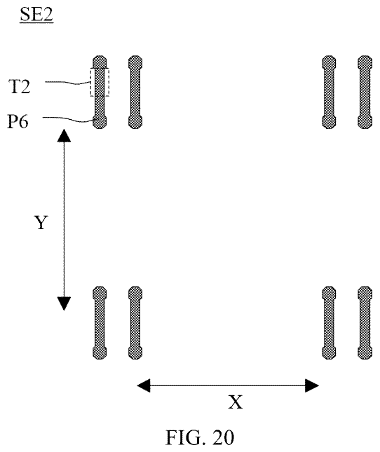

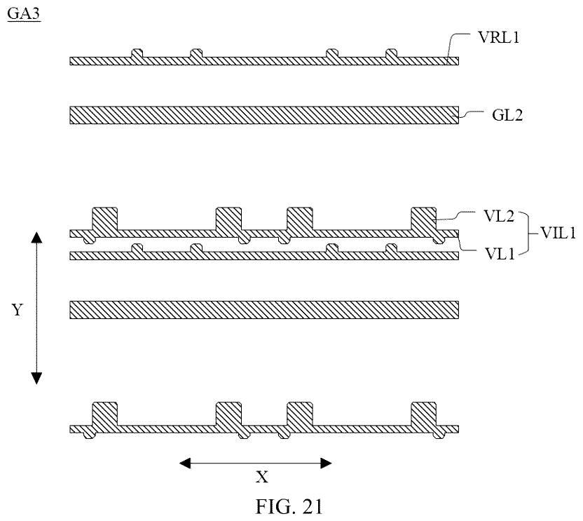

As shown in FIG. 10, FIG. 13 and FIG. 20, the second semiconductor layer IG can be arranged on a side of the second gate layer GA2 away from the substrate SU, and includes the active parts of the sixth semiconductor part P6 and the compensation transistor T2. The material of the second semiconductor layer IG can be a metal oxide such as IGZO.

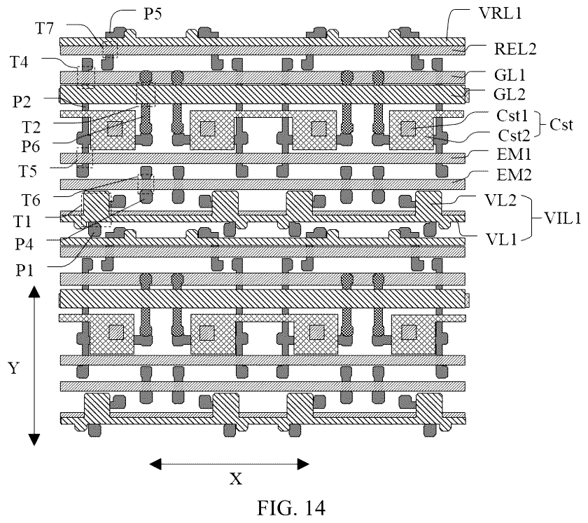

As shown in FIG. 10, FIG. 14 and FIG. 21, the third gate layer GA3 can be arranged on a side of the second semiconductor layer IG away from the substrate SU, and overlap with the second semiconductor layer IG. The third gate layer GA3 may include the gate electrode of the compensation transistor T2 and the second scan line GL2, and the area where the second scan line GL2 overlaps with the second semiconductor layer IG is the gate electrode of the compensation transistor T2.

In addition, in some embodiments, as shown in FIG. 13 and FIG. 19, the second gate layer GA2 may further include an auxiliary scan line GLs, which may extend along the row direction X and overlap with the second semiconductor layer IG, and the overlapping area may serve as the gate electrode of the compensation transistor T2. That is, the compensation transistor T2 includes a top gate (second scan line GL2) and a bottom gate (auxiliary scan line GLs). The second scan lines GL2 are overlapped in one-to-one correspondence, and the two may be connected in the peripheral area WA, thereby transmitting the second scan signal G2 at the same time to improve the stability of the signal. Meanwhile, the auxiliary scan line GLs may also shield the active part of the compensation transistor T2 to avoid the influence of the signal and light below.

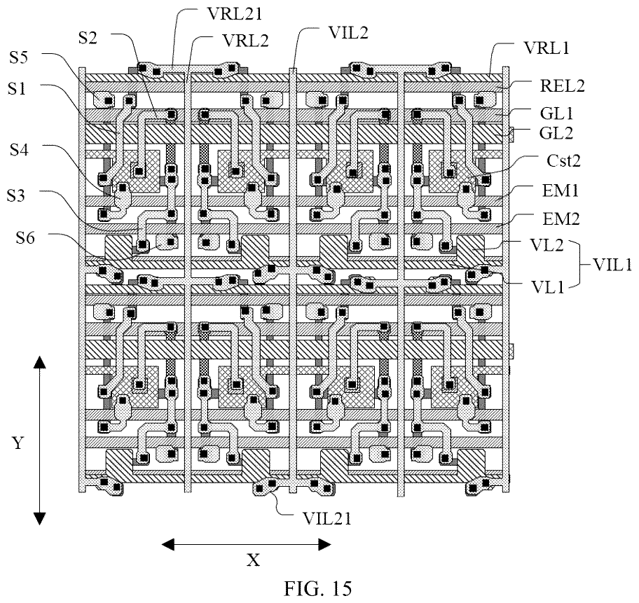

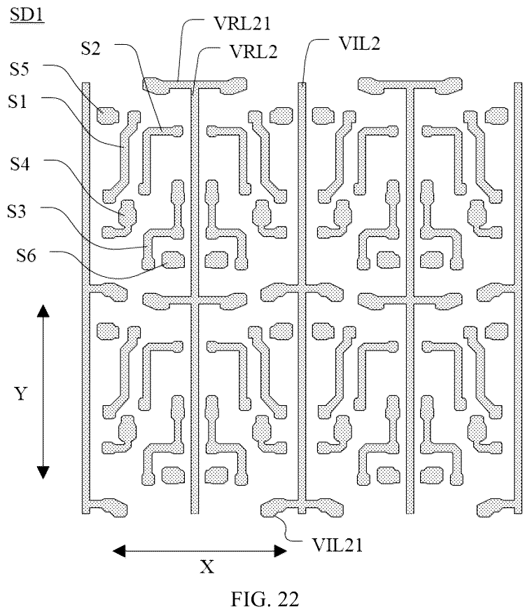

As shown in FIG. 10, FIG. 15 and FIG. 22, the first source-drain layer SD1 may be arranged on a side of the third gate layer GA3 away from the substrate SU, and may connect part of the transistors and the storage capacitors Cst.

In some embodiments of the present disclosure, the first source-drain layer SD1 may include first to sixth connection parts (S1-S6), where the first connection part S1 may be connected to the second electrode of the second reset transistor T7, the second electrode of the write transistor T4, and the second electrode of the first light-emitting control transistor T5 through a contact hole. The second connection part S2 may be connected to the second electrode of the compensation transistor T2 and the first plate Cst1 (gate electrode of the drive transistor T3) of the storage capacitor Cst through a contact hole. For the convenience of connection, a through hole for the contact hole to pass through may be provided in the second plate Cst2. The third connection part S3 may be connected to the second electrode of the first reset transistor T1, the first electrode of the second light-emitting control transistor T6, and the second electrode of the drive transistor T3 through a contact hole. The fourth connection part S4 is connected to the first electrode of the first light-emitting control transistor T5 and the second plate Cst2 through a contact hole, and is configured to connect to the power line VDL. The fifth connection part S5 is connected to the first electrode of the write transistor T4 through a contact hole, and is configured to connect to the data line DAL. The sixth connection part S6 is connected to the second electrode of the second light-emitting control transistor T6 through a contact hole, and is configured to connect to the first electrode of the light emitting device LS.

As shown in FIG. 15 and FIG. 22, in some embodiments of the present disclosure, for a first connection part S1 of a pixel circuit, it can extend along the column direction Y and overlap with at least a part of the first scan line GL1, the second scan line GL2, and the second plate Cst2 of the pixel circuit.

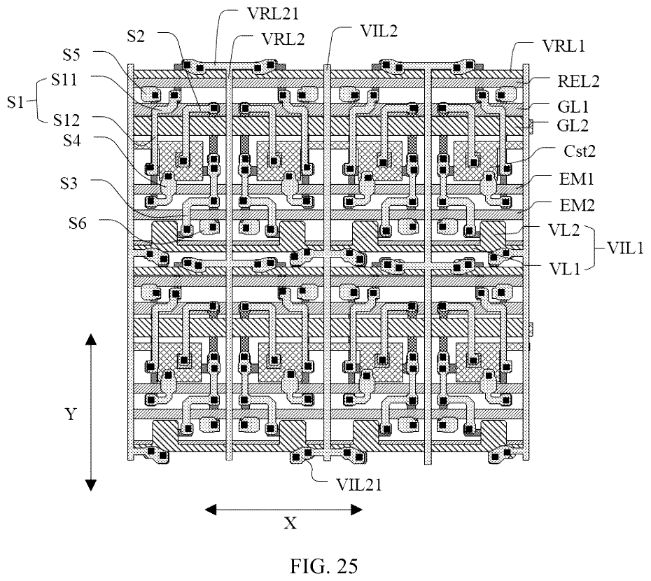

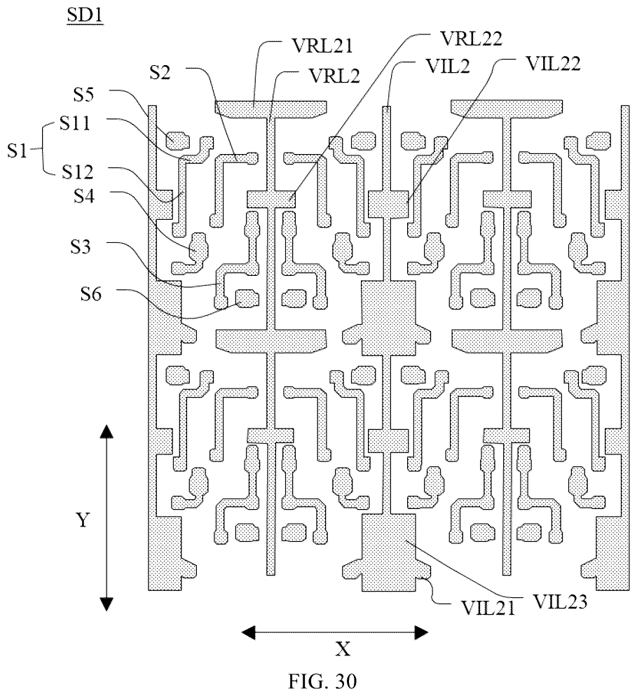

As shown in FIG. 25 and FIG. 30, in some embodiments of the present disclosure, for a first connection part S1 of a pixel circuit, it can extend along the column direction Y and overlap with the first scan line GL1 and the second scan line GL2 of the pixel circuit, but not overlap with the second plate Cst2, so as to avoid the parasitic capacitance generated between the second plate Cst2 the first connection part S1, thereby reducing the parasitic capacitance on the first connection part S1, and making the reset more accurate. For example, the first connection part S1 may include a first segment S11 and a second segment S12. The first segment S11 may extend along the row direction X and overlap with the first scan line GL1. One end of the first segment S11 is connected to the second electrode of the second reset transistor T7. The second segment S12 may extend along the column direction Y and connect to the first segment S11, the second electrode of the write transistor T4 and the second electrode of the first light-emitting control transistor T5. The second segment S12 may overlap with the second semiconductor part P2, but not overlap with the second plate Cst2.

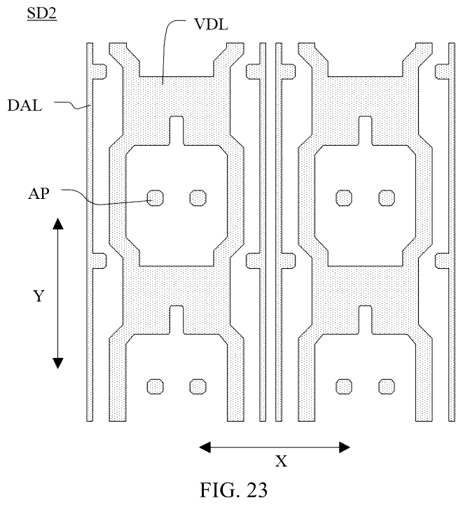

As shown in FIG. 10 and FIG. 23, the second source-drain layer SD2 is disposed on a side of the first source-drain layer SD1 away from the substrate SU, and includes a power line VDL and a data line DAL extending along the column direction Y. The power line VDL may be connected to the fourth connection part S4 through a contact hole, and thus connected to the first electrode of the first light-emitting control transistor T5 and the second plate Cst2, so as to transmit the first power signal VDD. The data line DAL may be connected to the fifth connection part S5 through a contact hole, and thus connected to the first electrode of the write transistor T4, so as to transmit the data signal DA. In addition, the second source-drain layer SD2 may further include an adapter part AP, which may be connected to the sixth connection part S6 through a contact hole, and the first electrode of the light-emitting device may be connected to the sixth connection part through the adapter part AP.

The scheme for inputting the first reset signal Vinit and the second reset signal Vref is described below:

Traces for transmitting the first reset signal Vinit and the second reset signal Vref may be set in any one or more layers from the first gate layer GA1 to the second source-drain layer SD2, and the traces may be connected to the first electrode of the first reset transistor T1 and the first electrode of the second reset transistor T7.

In order to reduce impedance and increase refresh rate, the first reset signal Vinit may be transmitted using a mesh structure formed by traces of different layers.

In some embodiments of the present disclosure, the circuit layer CL may include a first reset signal network, which may be connected to the first electrode of the first reset transistor T1 for transmitting the first reset signal Vinit. The first reset signal network may include a first signal line VIL1 and a second signal line VIL2 located in different layers and connected; the first signal line VIL1 may extend along the row direction X, and the second signal line VIL2 may extend along the column direction Y.

As shown in FIG. 14, FIG. 15, FIG. 21 and FIG. 22, for example, the first signal line VIL1 is located in the third gate layer GA3, the second signal line VIL2 may be located in the first source-drain layer SD1, and the first signal line VIL1 and the second signal line VIL2 are connected through a contact hole. There are multiple first signal lines VIL1 and second signal lines VIL2, and respective first signal lines VIL1 are spaced along the column direction Y, and the second signal lines VIL2 are spaced along the row direction X. A first signal line VIL1 overlaps with respective first semiconductor parts P1 including the active parts of the first reset transistors T1 of the same row of pixel circuits along the row direction X. A second signal line VIL2 may be provided between two adjacent columns of pixel circuits.

In some embodiments of the present disclosure, the circuit layer CL may include a second reset signal Vref network. The second reset signal Vref network may be connected to the first electrode of the second reset transistor T7 for transmitting the second reset signal Vref. The second reset signal Vref network includes a third signal line VRL1 and a fourth signal line VRL2 located in different layers and connected. The third signal line VRL1 extends along the row direction X, and the fourth signal line VRL2 extends along the column direction Y.

As shown in FIG. 14, FIG. 15, FIG. 21 and FIG. 22, for example, the third signal line VRL1 is located in the third gate layer GA3, and the fourth signal line VRL2 may be located in the first source-drain layer SD1, and the third signal line VRL1 and the fourth signal line VRL2 are connected through a contact hole. The number of the third signal line VRL1 and the fourth signal line VRL2 is multiple, and respective third signal lines VRL1 are spaced along the column direction Y, and respective fourth signal lines VRL2 are spaced along the row direction X. A third signal line VRL1 overlaps with respective fifth semiconductor parts P5 including the active parts of the second reset transistors T7 of the same row of pixel circuits along the row direction X. A fourth signal line VRL2 may be provided between two adjacent columns of pixel circuits.

In some embodiments of the present disclosure, respective columns of pixel circuits may be divided into a plurality of circuit groups distributed along the row direction X, and the same circuit group may include two adjacent columns of pixel circuits.

The two columns of pixel circuits of the same circuit group may be symmetrical about a symmetry axis extending along the column direction Y. The two adjacent circuit groups are symmetrical about a symmetry axis extending along the column direction Y. That is, in the two adjacent columns of pixel circuits, any two adjacent pixel circuits in the row direction X are symmetrical. Symmetry here means that the patterns from the first semiconductor layer SE1 to the first source-drain layer SD1 are symmetrical about the symmetry axis.

As shown in FIG. 15 and FIG. 22, in some embodiments, the second signal line VIL2 and the fourth signal line VRL2 can be alternately distributed along the row direction X, and the first reset signal Vinit and the second reset signal Vref are both DC signals, which can shield the signal crosstalk between different pixel circuits.

The second signal line VIL2 and each circuit group are alternately distributed along the row direction X. That is, a second signal line VIL2 is provided between two adjacent circuit groups. The second signal line VIL2 is simultaneously connected to the first electrodes of the first reset transistors T1 of the pixel circuits adjacent to it. For example, the second signal line VIL2 has a first lead-out part VIL21 extending toward both sides along the row direction X, and the first lead-out part VIL21 can be connected to the first signal line VIL1 through a contact hole, and can be connected to the first electrodes of the first reset transistors T1 of the pixel circuits on both sides of the second signal line VIL2.

A fourth signal line VRL2 is provided between two columns of pixel circuits of the same circuit group. The fourth signal line VRL2 is simultaneously connected to the first electrodes of the second reset transistors T7 of the pixel circuits adjacent thereto. For example, the fourth signal line VRL2 has a second lead-out part VRL21 extending toward both sides along the row direction X. The second lead-out part VRL21 can be connected to the third signal line VRL1 through a contact hole, and can be connected to the first electrodes of the second reset transistors T7 of the pixel circuits on both sides of the fourth signal line VRL2.

As shown in FIG. 12 to FIG. 14 and FIG. 21, in some embodiments of the present disclosure, the active part of the first reset transistor T1 can be shielded by the first signal line VIL1. For example, a first signal line VIL1 can overlap with the active part of each first reset transistor T1 of a row of pixel circuits. The shielding effect of the first reset signal Vinit can prevent the upper signal from interfering with the first reset transistor T1, and the first signal line VIL1 can shield the light to reduce the influence of the light on the first reset transistor T1. At the same time, a parasitic capacitor may be formed between the active part of the first reset transistor T1 and the first signal line VIL1, and the parasitic capacitor for transmitting the first signal may stabilize the voltage of the active part of the first reset transistor T1 to prevent leakage. For example:

As shown in FIG. 12 to FIG. 14 and FIG. 17, the active part of the first reset transistor T1 may include two channel parts CP and a connecting doped part DP connecting the two channel parts CP. The first reset control line REL1 may overlap with the two channel parts CP at the same time, but not overlap with the connecting doped part DP, and the area where the first reset control line REL1 overlaps with the channel part CP is the gate electrode of the first reset transistor T1, that is, the first reset transistor T1 has two gate electrodes. The two connected channels can increase the difficulty of leakage and prevent the first reset transistor T1 from leaking.

The first signal line VIL1 may include a line body VL1 extending along the row direction X and a plurality of overlapping parts VL2 distributed along the row direction X. Each overlapping part VL2 is connected to the same side of the line body VL1, and each overlapping part VL2 extends along the column direction Y.

Each overlapping part VL2 of a first signal line VIL1 may overlap with at least one channel part CP and the connecting doped part DP of each first reset transistor T1 of a row of pixel circuits. The line body VL1 of a first signal line VIL1 overlaps with at least one channel part CP of each first reset transistor T1 of a row of pixel circuits. Thus, the channel part CP and the connecting doped part DP are shielded by the line body VL1 and the overlapping part VL2. At the same time, a parasitic capacitor may be formed between the overlapping part VL2 and the connecting doped part DP, which is beneficial to prevent leakage.

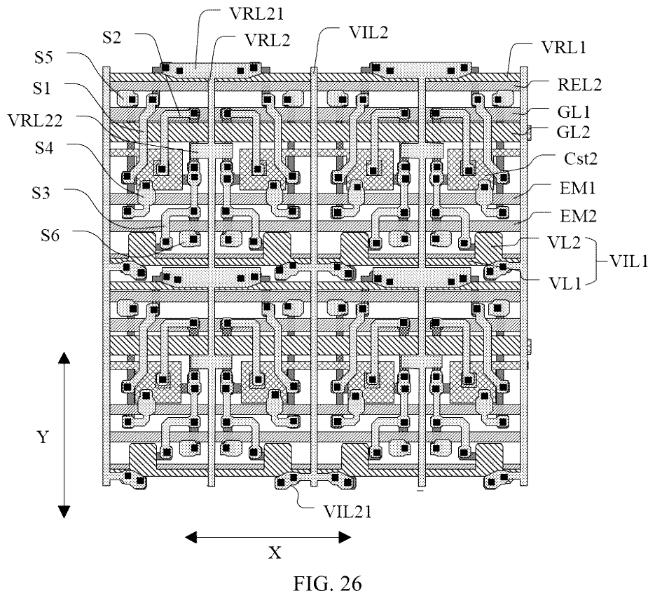

As shown in FIG. 26, in some embodiments of the present disclosure, for a fourth signal line VRL2 connected to two adjacent pixel circuits in the same row in a circuit group, it has a first extension part VRL22 protruding to at least one side along the row direction X, and the first extension part VRL22 is located between the second plates Cst2 of the two columns of pixel circuits, and the local line width of the fourth signal line VRL2 can be increased by the first extension part VRL22, thereby reducing the resistance. At the same time, the first extension part VRL22 can overlap with the sixth semiconductor part P6, making full use of the space and increasing the line width. At the same time, the width of the second lead-out part VRL21 can be greater than the width of the third signal line VRL1, and the second lead-out part VRL21 overlaps with the third signal line VRL1. The second lead-out part VRL21 can also increase the local line width of the fourth signal line VRL2, thereby reducing the resistance.

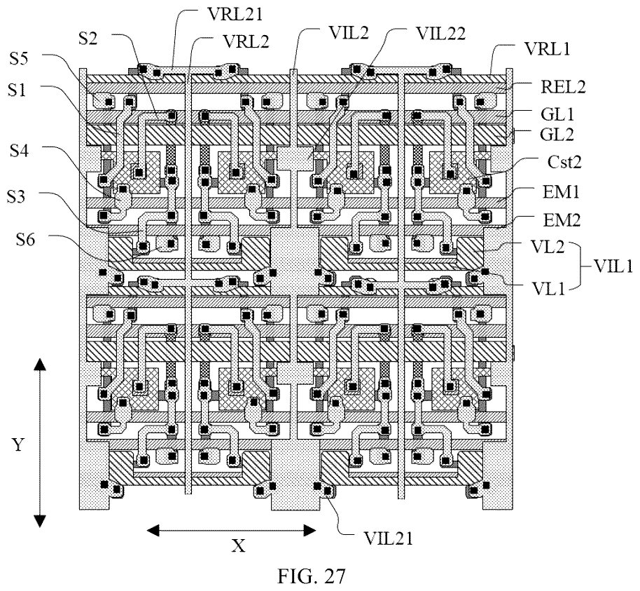

As shown in FIG. 27, in some embodiments of the present disclosure, for the second signal line VIL2 connected to the adjacent two pixel circuits in the same row of the adjacent two circuit groups, it can have a second extension part VIL22 protruding to at least one side along the row direction X, and the second extension part VIL22 can be located between the second plates Cst2 of the storage capacitors Cst of the two pixel circuits, increasing the local line width of the second signal line VIL2, thereby reducing the resistance. At the same time, the second signal line VIL2 may also have a third extension part VIL23 protruding to at least one side along the row direction X. The third extension part VIL23 is located between two adjacent overlapping parts VL2 and does not overlap with the overlapping part VL2, but overlaps with the line body VL1 connected to the pixel circuit of this row, the second light-emitting control line EML2 and the third signal line VRL1 connected to the pixel circuit of the next row, and the first lead-out part VIL21 is further protruded outward from the third extension part VIL23. The local line width of the second signal line VIL2 can be increased by the third extension part VIL23, thereby reducing the resistance.

In addition, the data line DAL can overlap with the second extension part VIL22 and the third extension part VIL23, and the third extension part VIL23 can shield the interference of the signals of the line body VL1, the second light-emitting control line EML2 and the third signal line VRL1 on the data signal.

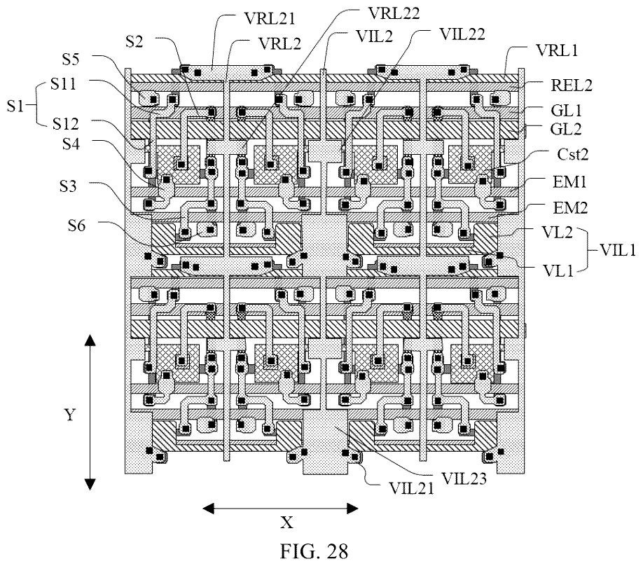

As shown in FIG. 28 and FIG. 30, the embodiments shown therein combine the schemes of FIG. 25 to FIG. 27 above, which will not be described in detail here.

As shown in FIG. 10, in some embodiments of the present disclosure, the second plate Cst2 of the storage capacitor Cst of the same column of pixel circuits can be connected to the same power line VDL. At the same time, in any row of pixel circuits, the second plates Cst2 of two adjacent pixel circuits belonging to different circuit groups can be connected as an integrated structure, while the second plates Cst2 belonging to the same circuit group can be disconnected in the row direction X. Two adjacent power lines VDL can be connected by connecting the second plates Cst2 to each other, which is beneficial to increase the area of the path for transmitting the first power signal VDD and reduce the impedance. Furthermore, the power lines VDL connected to the two pixel circuits of the same circuit group can be connected as an integrated structure along the row direction X, thereby connecting all power lines VDL as a whole.

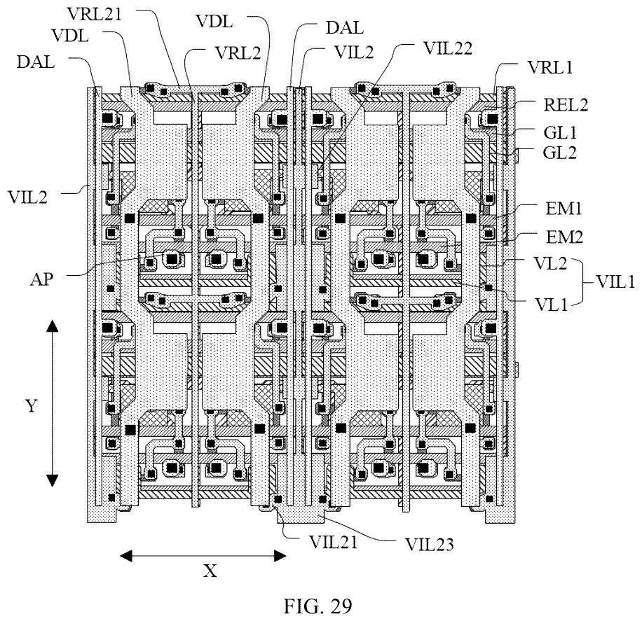

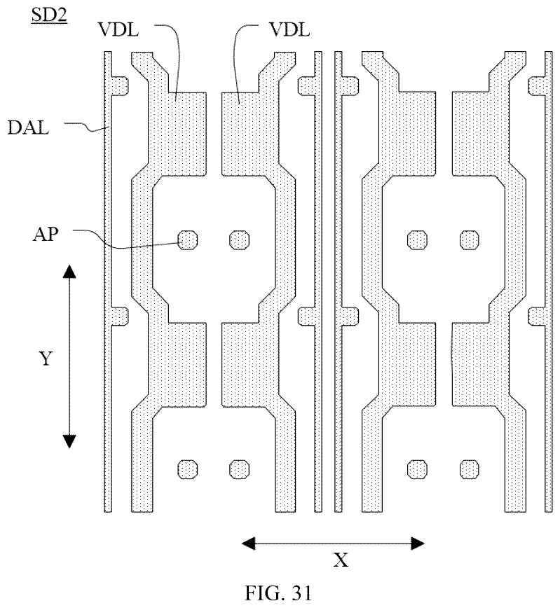

As shown in FIG. 29 and FIG. 31, in some embodiments of the present disclosure, the power lines VDL connecting to the two pixel circuits of the same circuit group can be arranged at intervals along the row direction X, that is, the two are disconnected, and the fourth signal line VRL2 connecting to the two columns of pixel circuits of the same circuit group can be located between the two power lines VDL, and partially overlap or not overlap with the power line VDL, thereby reducing the parasitic capacitance of the fourth signal line VRL2, thereby reducing the voltage drop, and making the reset of the same column of pixel circuits more uniform.

As shown in FIG. 10, in some embodiments of the present disclosure, a power line VDL overlaps with the active part of the drive transistor T3 and storage capacitor Cst of a column of pixel circuits connected thereto, and shields the N1 node. At the same time, the power line VDL can also overlap with the active part of the compensation transistor T2, so that the power line VDL can play a role in signal shielding, ensuring that the voltages of the N1 node and the compensation transistor T2 are stable and not easy to leak, and can shield light, reducing the influence of light on the drive transistor T3 and the compensation transistor T2.

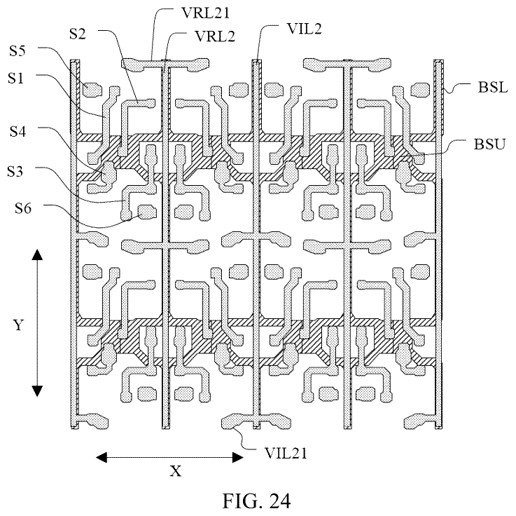

As shown in FIG. 24, in some embodiments of the present disclosure, the light shielding units BSU overlapping with the drive transistors T3 of the same circuit group can be connected as an integrated structure, and the light shielding units BSU of adjacent circuit groups can also be connected by traces. At the same time, in order to improve the transmittance, the connecting line BSL of the light shielding layer BSM can be overlapped with the second signal line VIL2 and the fourth signal line VRL2 to reduce the blocking of light.

Further, the circuit layer CL may also include a buffer layer BUF, a first gate insulating layer GI1, a second gate insulating layer GI2, a first insulating layer IL1, a third gate insulating layer GI3, a second insulating layer IL2, a first planarization layer PLN1 and a second planarization layer PLN2, where:

The light shielding layer BSM is stacked on the substrate SU, and the buffer layer BUF may cover the light shielding layer BSM, and the material of the buffer layer BUF may include inorganic materials such as silicon nitride and silicon oxide. The buffer layer BUF may be a single-layer or multi-layer structure, and the materials of different layers may be different. The first semiconductor layer SE1 is arranged on the surface of the buffer layer BUF away from the substrate SU.

The first gate insulating layer GI1 covers the first semiconductor layer SE1, and the material of the first gate insulating layer GI1 may include inorganic materials such as silicon nitride and silicon oxide. The first gate layer GA1 is arranged on the surface of the first gate insulating layer GI1 away from the substrate SU.

The second gate insulating layer GI2 covers the first gate layer GA1, and the material of the second gate insulating layer GI2 may include inorganic materials such as silicon nitride and silicon oxide. The second gate layer GA2 is arranged on the surface of the second gate insulating layer GI2 away from the substrate SU.

The first insulating layer IL1 may cover the second gate layer GA2, and the material of the first insulating layer IL1 may include inorganic materials such as silicon nitride and silicon oxide. The first insulating layer IL1 may be a single-layer or multi-layer structure, and the materials of different layers may be different. The second semiconductor layer SE2 is arranged on the surface of the first insulating layer IL1 away from the substrate SU.

The third gate insulating layer GI3 covers the second semiconductor layer SE2, and the material of the third gate insulating layer GI3 may include inorganic materials such as silicon nitride and silicon oxide. The third gate layer GA3 is arranged on the surface of the third gate insulating layer GI3 away from the substrate SU.

The second insulating layer IL2 may cover the third gate layer GA3, and the material of the second insulating layer IL2 may include inorganic materials such as silicon nitride and silicon oxide. The second insulating layer IL2 may be a single layer or a multi-layer structure, and the materials of different layers may be different. The first source-drain layer SD1 is disposed on the surface of the second insulating layer IL2 away from the substrate SU.

The first planarization layer PLN1 may cover the first source-drain layer SD1, and the material of the first planarization layer PLN1 may be an organic material such as a resin, and planarization may be achieved by leveling the organic material. The second source-drain layer SD2 may be disposed on the surface of the first planarization layer PLN1 away from the substrate SU. In addition, in some embodiments, the first source-drain layer SD1 may be covered with a passivation layer, and the passivation layer may be covered with the first planarization layer PLN1.

The second planarization layer PLN2 may cover the second source-drain layer SD2, and the material of the second planarization layer PLN2 may be an organic material such as a resin, and planarization may be achieved by leveling the organic material. The first electrode of the light-emitting device LD and the pixel definition layer PDL may be disposed on the surface of the second planarization layer PLN2 away from the substrate SU.

After considering the specification and practicing the present disclosure herein, those skilled in the art will easily think of other embodiments of the present disclosure. This application is intended to cover any variation, use or adaptation of the present disclosure, which follows the general principles of the present disclosure and includes common knowledge or customary technical means in the technical field not disclosed in the present disclosure. The description and examples are to be regarded as exemplary only, and the true scope and spirit of the present disclosure are indicated by the appended claims.

1. A pixel circuit, comprising a drive transistor, a compensation circuit, a write circuit, a first reset circuit and a second reset circuit;
a first electrode of the drive transistor is configured to receive a first power signal, and a second electrode of the drive transistor is connected to a light-emitting device through a first light-emitting control circuit;
one of the first electrode and the second electrode of the drive transistor is connected to a gate electrode of the drive transistor through the compensation circuit, and the other one of the first electrode and the second electrode of the drive transistor receives a data signal through the write circuit; and
the first reset circuit is connected to one of the first electrode and the second electrode of the drive transistor for inputting a first reset signal; the second reset circuit is connected to one of the first electrode and the second electrode of the drive transistor for inputting a second reset signal; the first reset signal and the second reset signal have opposite polarities.

2. The pixel circuit according to claim 1, wherein the first reset circuit, the second reset circuit, the compensation circuit and the write circuit are configured in one of the following manner:
the first reset circuit and the compensation circuit are connected to the second electrode of the drive transistor, and the second reset circuit and the write circuit are connected to the first electrode of the drive transistor;
the first reset circuit, the second reset circuit and the compensation circuit are connected to the second electrode of the drive transistor, and the write circuit is connected to the first electrode of the drive transistor;
the compensation circuit and the first reset circuit are connected to the first electrode of the drive transistor, and the second reset circuit and the write circuit are connected to the second electrode of the drive transistor; and
the first reset circuit, the second reset circuit and the compensation circuit are connected to the first electrode of the drive transistor, and the write circuit is connected to the second electrode of the drive transistor.

3-5. (canceled)

6. The pixel circuit according to claim 1, wherein the pixel circuit further comprises an energy storage circuit, a first light-emitting control circuit and a second light-emitting control circuit;
the first electrode of the drive transistor receives the first power signal through the first light-emitting control circuit, and the second electrode of the drive transistor is connected to the light-emitting device through the second light-emitting control circuit; and
the energy storage circuit is connected to the gate electrode of the drive transistor and is capable of receiving the first power signal.

7. The pixel circuit according to claim 6, wherein the compensation circuit comprises a compensation transistor, the write circuit comprises a write transistor, the first reset circuit comprises a first reset transistor, the second reset circuit comprises a second reset transistor, the first light-emitting control circuit comprises a first light-emitting control transistor, the second light-emitting control circuit comprises a second light-emitting control transistor; the energy storage circuit comprises a storage capacitor.

8. A driving method for a pixel circuit, the pixel circuit comprising a drive transistor, a compensation circuit, a write circuit, a first reset circuit, a second reset circuit, a first light-emitting control circuit and a second light-emitting control circuit;
a first electrode of the drive transistor receives a first power signal through the first light-emitting control circuit, and a second electrode of the drive transistor is connected to a light-emitting device through the second light-emitting control circuit; one of the first electrode and the second electrode of the drive transistor is connected to a gate electrode of the drive transistor through the compensation circuit, and the other one of the first electrode and the second electrode of the drive transistor receives a data signal through the write circuit; the first reset circuit is connected to one of the first electrode and the second electrode of the drive transistor; the second reset circuit is connected to one of the first electrode and the second electrode of the drive transistor;
the driving method comprises:
in a first reset stage of a write frame, turning off the write circuit, the first reset circuit, the first light-emitting control circuit and the second light-emitting control circuit; turning on the second reset circuit, and inputting a second reset signal through the second reset circuit;
in a second reset stage of the write frame, turning off the write circuit, the second reset circuit, the first light-emitting control circuit and the second light-emitting control circuit; turning on the compensation circuit and the first reset circuit, and inputting a first reset signal through the first reset circuit; the first reset signal and the second reset signal have opposite polarities;
in a write stage of the write frame, turning off the first reset circuit, the second reset circuit, the first light-emitting control circuit and the second light-emitting control circuit; turning on the write circuit and the compensation circuit, and inputting the data signal through the write circuit;
in a third reset stage of the write frame, turning off the compensation circuit, the write circuit, the second reset circuit and the first light-emitting control circuit; turning on the first reset circuit and the second light-emitting control circuit, and inputting the first reset signal through the first reset circuit; and
in a light-emitting stage of the write frame, turning off the compensation circuit, the write circuit, the first reset circuit and the second reset circuit; turning on the first light-emitting control circuit and the second light-emitting control circuit.

9. The driving method according to claim 8, further comprising:
in a first reset stage of a hold frame, turning off the write circuit, the first reset circuit, the first light-emitting control circuit and the second light-emitting control circuit; turning on the second reset circuit, and inputting the second reset signal through the second reset circuit;
in a second reset stage of the hold frame, turning off the write circuit, the second reset circuit, the first light-emitting control circuit and the second light-emitting control circuit;
turning on the compensation circuit and the first reset circuit, and inputting the first reset signal through the first reset circuit; and
in a third reset stage of the hold frame, turning off the compensation circuit, the write circuit, the second reset circuit and the first light-emitting control circuit; turning on the first reset circuit and the second light-emitting control circuit, and inputting the first reset signal through the first reset circuit.

10. The driving method according to claim 9, further comprising:
in a fourth reset stage of the hold frame, turning off the first reset circuit, the second reset circuit, the first light-emitting control circuit and the second light-emitting control circuit; turning on the write circuit and the compensation circuit, and inputting the data signal through the write circuit.

11. The driving method according to claim 9, wherein the compensation circuit is turned on in the first reset stage of the write frame and the hold frame.

12. The driving method according to claim 8, wherein there are multiple pixel circuits and the multiple pixel circuits are arranged in an array along a row direction and a column direction;
the first light-emitting control circuit is capable of being turned on in response to a first light-emitting control signal, and the second light-emitting control circuit is capable of being turned on in response to a second light-emitting control signal; the write circuit is capable of being turned on in response to a first scan signal; and
the first light-emitting control signal input to the pixel circuit of a n-th row is multiplexed into the second light-emitting control signal input to the pixel circuit of a (n+i)-th row.

13. The driving method according to claim 8, wherein there are multiple pixel circuits and the multiple pixel circuits are arranged in an array along a row direction and a column direction;
the write circuit is capable of being turned on in response to a first scan signal, and the second reset circuit is capable of being turned on in response to a second reset control signal; and
the first scan signal input to the pixel circuit of a n-th row is multiplexed into the second reset control signal input to the pixel circuit of a (n+j)-th row.

14. A display panel, comprising a plurality of pixel circuits arranged in an array along a row direction and a column direction, the pixel circuit comprising a plurality of transistors, a storage capacitor, a data line and a power line, the transistors comprising a drive transistor, a write transistor, a compensation transistor, a first light-emitting control transistor, a second light-emitting control transistor, a first reset transistor and a second reset transistor;
a first electrode of the drive transistor is connected to the power line through the first light-emitting control transistor, and a second electrode of the drive transistor is connected to a light-emitting device through the second light-emitting control transistor; one of the first electrode and the second electrode of the drive transistor is connected to a gate electrode of the drive transistor through the compensation transistor, and the other one of the first electrode and the second electrode of the drive transistor is connected to the data line through the write transistor;
the first reset transistor is connected to one of the first electrode and the second electrode of the drive transistor; the second reset transistor is connected to one of the first electrode and the second electrode of the drive transistor; the storage capacitor connects the gate electrode of the drive transistor and the power line; the power line is configured to input a first power signal, and the data line is configured to transmit a data signal;
the display panel comprises:
a substrate;
a circuit layer, arranged on a side of the substrate, and comprising the pixel circuits; and
a plurality of light-emitting devices, arranged on a side of the circuit layer away from the substrate, and one of the light-emitting devices is connected to the second electrode of the second light-emitting control transistor of one of the pixel circuits.

15. The display panel according to claim 14, wherein the circuit layer comprises:
a first reset signal network connected to a first electrode of the first reset transistor for transmitting a first reset signal; the first reset signal network comprises a first signal line and a second signal line located in different layers and connected; the first signal line extends along the row direction, and the second signal line extends along the column direction.

16. The display panel according to claim 15, wherein the circuit layer comprises:
a second reset signal network connected to the first electrode of the second reset transistor for transmitting a second reset signal; the second reset signal network comprises a third signal line and a fourth signal line located in different layers and connected; the third signal line extends along the row direction, and the fourth signal line extends along the column direction.

17. The display panel according to claim 16, wherein the circuit layer further comprises:
a light shielding layer, arranged on a side of the substrate;
a first semiconductor layer, arranged on a side of the light shielding layer away from the light shielding layer, and comprising active parts of the drive transistor, the write transistor, the first light-emitting control transistor, the second light-emitting control transistor, the first reset transistor, and the second reset transistor;
a first gate layer, arranged on a side of the first semiconductor layer away from the substrate, and overlapping with the first semiconductor layer; the first gate layer comprises a first plate of the storage capacitor, and gate electrodes of the drive transistor, the write transistor, the first light-emitting control transistor, the second light-emitting control transistor, the first reset transistor, and the second reset transistor;
a second gate layer, arranged on a side of the first gate layer away from the substrate, and comprising a second plate of the storage capacitor;
a second semiconductor layer, arranged on a side of the second gate layer away from the substrate and comprising an active part of the compensation transistor;
a third gate layer, arranged on a side of the second semiconductor layer away from the substrate and overlapping with the second semiconductor layer; the third gate layer comprises a gate electrode of the compensation transistor, the first signal line and the third signal line;
a first source-drain layer, arranged on a side of the third gate layer away from the substrate and comprising the second signal line and the fourth signal line; and
a second source-drain layer, arranged on a side of the first source-drain layer away from the substrate and comprising the power line and the data line.

18. The display panel according to claim 16, wherein respective columns of the pixel circuits are divided into a plurality of circuit groups distributed along the row direction, and the same circuit group comprises two adjacent columns of the pixel circuits;
two columns of the pixel circuits in the same circuit group are symmetrical about a symmetry axis extending along the column direction; and two adjacent circuit groups are symmetrical about a symmetry axis extending along the column direction.

19. The display panel according to claim 18, wherein the first signal line and the third signal line are alternately distributed along the column direction; the second signal line and the fourth signal line are alternately distributed along the row direction;
the second signal line and the circuit group are alternately distributed along the row direction; the second signal line is simultaneously connected to the first electrodes of the first reset transistors of the pixel circuits adjacent to the second signal line; and
the fourth signal line is provided between two columns of the pixel circuits in the same circuit group; the fourth signal line is simultaneously connected to the first electrodes of the second reset transistors of two columns of the pixel circuits adjacent to the fourth signal line.

20. The display panel according to claim 17, wherein the first signal line overlaps with the active part of each of the first reset transistors of a row of the pixel circuits.

21. The display panel according to claim 20, wherein the active part of the first reset transistor comprises two channel parts and a connecting doped part connecting the two channel parts;
the first signal line comprises a line body extending along the row direction and a plurality of overlapping parts distributed along the row direction, wherein the overlapping parts are connected to the line body and extend along the column direction;
each of the overlapping parts of the first signal line overlaps with at least one channel part and the connecting doped part of the active part of each of the first reset transistors of a row of the pixel circuits; the line body of the first signal line overlaps with at least one channel part of the active part of each of the first reset transistors of a row of the pixel circuits.

22. The display panel according to claim 18, wherein the second plates of the pixel circuits in the same column are connected to the same power line;
in any row of the pixel circuits, the second plates of the storage capacitors of two adjacent pixel circuits belonging to different circuit groups are connected.

23. The display panel according to claim 18, wherein the power line is connected to one column of the pixel circuits, and the power line overlaps with active parts of the drive transistors, active parts of the compensation transistors, and the storage capacitors of the one column of the pixel circuits connected to the power line.
